(19) United States
(12) Patent Application Publication
(10) Pub. No.: US 2026/0260694 A1
(43) Pub. Date: Sep. 3, 2026

(54) MEMORY DEVICE AND METHOD FOR OPERATING THEREOF

(71) Applicant: SK hynix Inc., Gyeonggi-do (KR)

(72) Inventor: Byung Goo CHO, Gyeonggi-do (KR)

(21) Appl. No.: 19/365,195

(22) Filed: Oct. 22, 2025

(30) Foreign Application Priority Data
Jan. 6, 2025 (KR) 10-2025-0001550

(51) Int. Cl. G11C 29/52; G11C 16/24; G11C 16/26; G11C 16/32

(52) U.S. Cl. CPC G11C 29/52; G11C 16/24; G11C 16/26; G11C 16/32

(57) ABSTRACT

A memory device according to an embodiment of the present disclosure includes a plurality of memory cells; a plurality of page buffers storing data in the plurality of memory cells or reading data from the plurality of memory cells; a plurality of bit lines connected between the plurality of memory cells and the plurality of page buffers; and a cyclic redundancy check unit including a collection unit collecting bit line data loaded on the plurality of bit lines and a calculation unit performing a cyclic redundancy check (CRC) on the collected bit line data.

### CROSS-REFERENCE TO RELATED APPLICATION

The present application claims priority under 35 U.S.C. § 119(a) to Korean patent application number 10-2025-0001550 filed on Jan. 6, 2025, the entire disclosure of which is incorporated herein by reference.

### BACKGROUND

### 1. Technical Field

The embodiments of the present disclosure generally relate to an electronic device, and more particularly, to a memory device and an operating method of the memory device.

### 2. Related Art

Non-volatile memories, such as flash memories, may be classified based on the number of bits stored in each memory cell into single-level cell (SLC), multi-level cell (MLC), triple-level cell (TLC), or even higher-level multi-level cells.

The TLC memory, offering high storage capacity, has become the most widely used type in recent years. While the TLC memory enables higher memory density compared to the SLC memory, it has lower reliability. To compensate for the lower reliability of the TLC memory, memory devices use cyclic redundancy check (CRC).

The cyclic redundancy check is performed on data for some configurations, including page buffers. However, the cyclic redundancy check is not performed on the data of a bit line connecting a page buffer and a memory cell because memory devices do not have a configuration to perform the cyclic redundancy check on the data of a bit line. Therefore, it is difficult for the designer to confirm the data consistency in the bit line, which is a data movement path between the page buffer and the memory cell for design verification. In the end, due to the consistency of bit line data that is not confirmed at the time of the design verification, reliability problems may occur in the memory device in the future.

### SUMMARY

Various embodiments of the present disclosure are directed to a memory device capable of improving the reliability thereof and an operating method thereof.

A memory device according to an embodiment of the present disclosure includes a plurality of memory cells; a plurality of page buffers storing data in the plurality of memory cells or reading data from the plurality of memory cells; a plurality of bit lines connected between the plurality of memory cells and the plurality of page buffers; and a cyclic redundancy check unit including a collection unit collecting bit line data loaded on the plurality of bit lines and a calculation unit performing a cyclic redundancy check (CRC) on the collected bit line data.

In addition, a method of operating a memory device according to an embodiment of the present disclosure includes loading first bit line data into a plurality of bit lines by performing a program operation or a read operation; selecting and collecting second bit line data from the first bit line data based on a bit line selection option; and performing a cyclic redundancy check on the selectively collected bit line data to generate a result value.

### BRIEF DESCRIPTION OF THE DRAWINGS

FIG. 1 is a diagram illustrating a memory device according to an embodiment of the present disclosure;

FIG. 2 is a diagram illustrating a memory block shown in FIG. 1;

FIG. 3 is a diagram illustrating the arrangement of a memory cell array and a peripheral circuit shown in FIG. 1;

FIG. 4 is a diagram illustrating a first page buffer among a plurality of page buffers of FIG. 1;

FIG. 5 is a diagram illustrating a cyclic redundancy check unit shown in FIG. 1;

FIG. 6 is a flowchart illustrating a method of operating a memory device according to an embodiment of the present disclosure;

FIG. 7 is a diagram illustrating a method of controlling a cyclic redundancy check operation of a control logic shown in FIGS. 5 and 6;

FIG. 8 is a diagram illustrating a memory card system to which a memory device according to an embodiment of the disclosure invention is applied; and

FIG. 9 is a diagram illustrating an SSD system to which a memory device is applied according to an embodiment of the present disclosure.

### DETAILED DESCRIPTION

Specific structural or functional descriptions disclosed herein are merely illustrative for the purpose of describing embodiments according to the concept of the present disclosure. Embodiments according to the concept of the present disclosure can be implemented in various forms and replaced with other equivalent embodiments, and they should not be construed as being limited to the specific embodiments set forth herein.

Hereinafter, the terms such as “first” and “second” may be used to describe various components. However, the components should not be limited by these terms. The above terms are used to distinguish one component from another component.

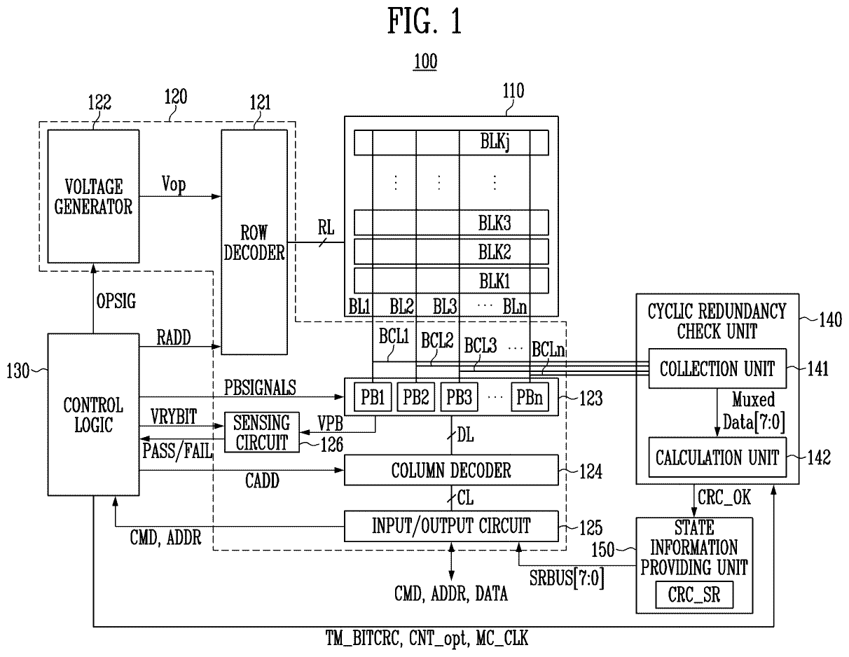

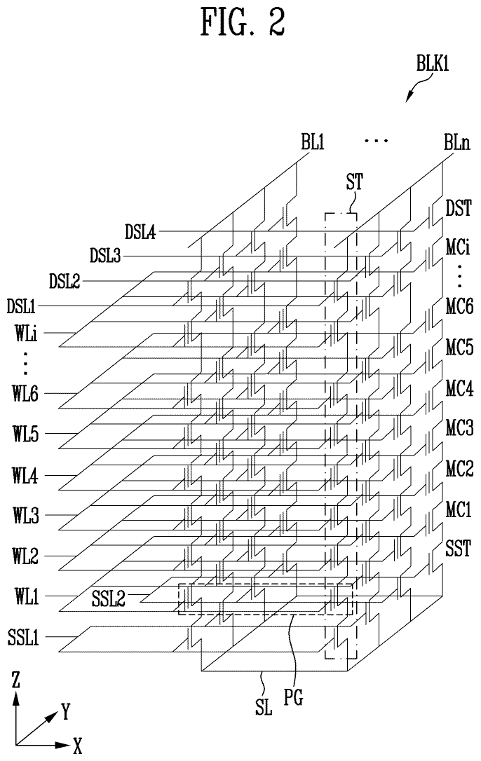

FIG. 1 is a diagram illustrating a memory device 100 according to an embodiment of the present disclosure. FIG. 2 is a diagram illustrating a memory block illustrated in FIG. 1.

Referring to FIGS. 1 and 2, the memory device 100 may include a memory cell array 110, a peripheral circuit 120, and a control logic 130.

The memory cell array 110 includes first to j-th memory blocks BLK1 to BLKj. The first to j-th memory blocks BLK1 to BLKj are connected to a row decoder 121 through row lines RL. The first to j-th memory blocks BLK1 to BLKj may be connected to a page buffer group 123 through bit lines BL1 to BLn. Each of the first to j-th memory blocks BLK1 to BLKj includes a plurality of cell strings ST, and each of the plurality of cell strings ST includes a plurality of memory cells. In an embodiment, the plurality of memory cells are non-volatile memory cells. Memory cells connected to the same word line may be defined as a single page PG. Thus, one memory block may include a plurality of pages.

The first to j-th memory blocks BLK1 to BLKj may be configured to be identical to each other, and the structure of the first memory block BLK1, for example, is described in detail below.

Referring to FIG. 2, the first memory block BLK1 includes the cell strings ST connected between the first to n-th bit lines BL1 to BLn and a source line SL. Because the first to n-th bit lines BL1 to BLn extend in a Y direction and are arranged spaced apart from each other in an X direction, the cell strings ST may also be arranged spaced apart in the X and Y directions. For example, the cell strings ST may be connected between the first bit line BL1 and the source line SL, and the cell strings ST may be arranged between the second bit line BL2 and the source line SL. In this way, the cell strings ST may be arranged between the n-th bit line BLn and the source line SL. The cell strings ST may extend in a Z direction.

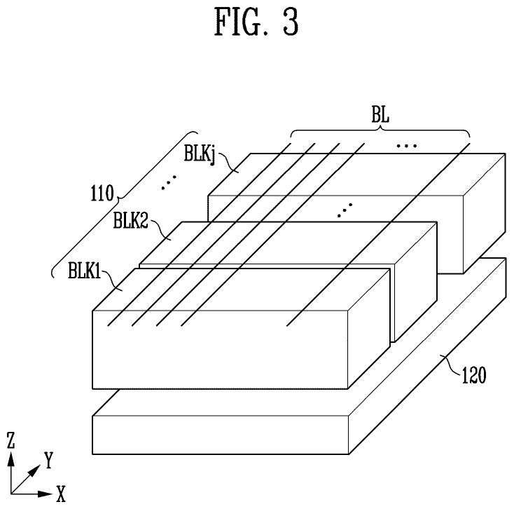

When one of the cell strings ST connected to the n-th bit line BLn is described as an example, the cell string ST may include a source select transistor SST, first to i-th memory cells MC1 to MCi, and a drain select transistor DST. Because the first memory block BLK1 shown in FIG. 3 is a diagram schematically illustrating the structure of the memory block, the number of the source select transistors SST, the first to i-th memory cells MC1 to MCi, and the drain select transistors DST included in the cell strings ST may be changed according to the memory device.

Gates of the source select transistors SST included in different cell strings may be connected to a first or second source select line SSL1 or SSL2, gates of the first to i-th memory cells MC1 to MCi may be connected to first to i-th word lines WL1 to WLi, and each of gates of the drain select transistors DST may be connected to one of first to fourth drain select lines DSL1 to DSL4.

To describe the lines connected to the first memory block BLK1 in more detail, the source select transistors SST arranged in the X direction may be connected to the same source select line as each other, and the source select transistors SST arranged in the Y direction may be connected to source select line separated from each other. For example, some of the source select transistors SST arranged in the Y direction may be connected to the first source select line SSL1, and the remaining source select transistors SST other than some source select transistors SST may be connected to the second source select line SSL2. The second source select line SSL2 is separated from the first source select line SSL1. Thus, a voltage applied to the first source select line SSL1 may be the same as or different from a voltage applied to the second source select line SSL2.

Memory cells formed in the same level among the first to i-th memory cells MC1 to MCi may be connected to the same word line. For example, the first memory cells MC1 included in different cell strings ST may be connected in common to the first word line WL1, and the i-th memory cells MCi included in different cell strings ST may be connected in common to the i-th word line WLi. The group of memory cells included in different cell strings ST and connected to the same word line forms the page PG. Program and read operations may be performed in units of pages PG, and pre-program and erase operations may be performed in units of memory blocks. Operations performed in units of memory blocks may be performed on all pages included in a selected memory block.

The drain select transistors DST arranged in the Y direction may be connected to the first to fourth drain select lines DSL1 to DSL4 separated from each other. Specifically, the drain select transistors DST arranged in the X direction may be connected to the same drain select line as each other, and the drain select transistors DST arranged in the Y direction may be connected to the first to fourth drain select lines DSL1 to DSL4 separated from each other. Because the first to fourth drain select lines DSL1 to DSL4 are separated from each other, different voltages may be applied to the first to fourth drain select lines DSL1 to DSL4.

Referring to FIGS. 1 and 2, the row lines RL may include the source select lines SSL1 and SSL2, the plurality of word lines WL1 to WLi, and the drain select lines DSL1 to DSL4. The source select lines SSL1 and SSL2, the plurality of word lines WL1 to WLi, and the drain select lines DSL1 to DSL4 may be connected to each of the first to j-th memory blocks BLK1 to BLKj. Each of the bit lines BL1 to BLn may be connected to at least one cell string.

Memory cells included in the memory cell array 110 may be programmed in a Multi-Level Cell (MLC) method, a Triple-Level Cell (TLC) method, or a Quad-Level Cell (QLC) method depending on the number of bits of data stored. Each of the memory cells programmed in the MLC method may store two bits of data. Each of the memory cells programmed in the TLC method may store three bits of data. Each of the memory cells programmed in the QLC method may store four bits of data. The methods in which the memory cells are programmed may be set differently depending on a memory device. In addition to the methods described above, a method of programming five bits or more of data in one memory cell may be used.

The peripheral circuit 120 may be configured to perform a program operation, a read operation, or an erase operation on a selected area of the memory cell array 110 under the control of the control logic 130. For example, the peripheral circuit 120 may apply various operating voltages to the row lines RL and the first to n-th bit lines BL1 to BLn, or selectively discharge the row lines RL and the first to n-th bit lines BL1 to BLn under the control of the control logic 130.

The peripheral circuit 120 may include the row decoder 121, a voltage generator 122, the page buffer group 123, a column decoder 124, an input/output circuit 125, and a sensing circuit 126.

The row decoder 121 is connected to the memory cell array 110 through the row lines RL. The row lines RL may include at least one source select line, a plurality of word lines, and at least one drain select line. In an embodiment, the word lines may include normal word lines and dummy word lines.

The row decoder 121 is configured to decode a row address RADD received from the control logic 130. The row decoder 121 selects at least one of the memory blocks BLK1 to BLKj according to the decoded address. In addition, the row decoder 121 may transfer operating voltages Vop generated by the voltage generator 122 to the row lines RL of the selected memory block according to the decoded address.

For example, during a program operation, the row decoder 121 may apply a program voltage to a selected word line and a program pass voltage at a level lower than that of the program voltage to unselected word lines. During a program verify operation, the row decoder 121 may apply a verify voltage to the selected word line and a verify pass voltage at a level higher than that of the verify voltage to the unselected word lines. During a read operation, the row decoder 121 may apply a read voltage to the selected word line and a read pass voltage at a level higher than that of the read voltage to the unselected word lines.

An erase operation of the memory device 100 is performed in units of memory blocks. During the erase operation, the row decoder 121 may select one memory block according to the decoded address. During the erase operation, the row decoder 121 may apply a voltage of 0 V or a ground voltage to word lines connected to the selected memory block, or cause the word lines to float.

The voltage generator 122 operates in response to the control of the control logic 130. The voltage generator 122 is configured to generate a plurality of voltages using an external power voltage supplied to the memory device 100. Specifically, the voltage generator 122 may generate the various operating voltages Vop used for the program, read, and erase operations in response to an operating signal OPSIG generated by the control logic 130. For example, the voltage generator 122 may generate a program voltage, a verify voltage, a pass voltage, a read voltage, an erase voltage, and the like in response to the control of the control logic 130.

The page buffer group 123 includes first to n-th page buffers PB1 to PBn. The first to n-th page buffers PB1 to PBn are connected to the memory cell array 110 through the first to n-th bit lines BL1 to BLn. The first to n-th page buffers PB1 to PBn operate in response to the control of the control logic 130. Specifically, the first to n-th page buffers PB1 to PBn may operate in response to page buffer control signals PBSIGNALS. For example, the first to n-th page buffers PB1 to PBn may temporarily store data received through the first to n-th bit lines BL1 to BLn, or sense a voltage or current of the first to n-th bit lines BL1 to BLn during the read or verify operation.

Specifically, during the program operation, when the program voltage is applied to the selected word line, the first to n-th page buffers PB1 to PBn may transfer data DATA received through the input/output circuit 125 to selected memory cells through the first to n-th bit lines BL1 to BLn. Memory cells of a selected page are programmed according to the transferred data DATA. During the program verify operation, the first to n-th page buffers PB1 to PBn sense the voltage or current received from the selected memory cells through the first to n-th bit lines BL1 to BLn to read page data.

During the read operation, the first to n-th page buffers PB1 to PBn read the data DATA from the memory cells of the selected page through the first to n-th bit lines BL1 to BLn, and output the read data DATA to the input/output circuit 125 under the control of the column decoder 124.

During the erase operation, the first to n-th page buffers PB1 to PBn may float the first to n-th bit lines BL1 to BLn or apply the erase voltage to the first to n-th bit lines BL1 to BLn.

The column decoder 124 may transfer data between the input/output circuit 125 and the page buffer group 123 in response to a column address CADD. For example, the column decoder 124 may exchange data with the first to n-th page buffers PB1 to PBn through data lines DL, or exchange data with the input/output circuit 125 through column lines CL.

The input/output circuit 125 may transfer a command CMD and an address ADDR received from a memory controller to the control logic 130, or may exchange the data DATA with the column decoder 124.

The sensing circuit 126 may generate a reference current in response to an allowable bit VRYBIT signal during the read operation or the verify operation, and compare a sensing voltage VPB received from the page buffer group 123 with a reference voltage generated by the reference current to output a pass signal PASS or a fail signal FAIL.

The control logic 130 may output the operation signal OPSIG, the row address RADD, the page buffer control signals PBSIGNALS, and the allow bit VRYBIT in response to the command CMD and the address ADDR to control the peripheral circuit 120. For example, the control logic 130 may control the read operation of the selected memory block in response to a sub-block read command and address. Further, the control logic 130 may control the erase operation of the selected sub-block included in the selected memory block in response to the sub-block erase command and address. In addition, the control logic 130 may determine whether the verify operation has been passed or failed in response to the pass or fail signal PASS or FAIL.

FIG. 3 is a diagram illustrating an arrangement of the memory cell array 110 and the peripheral circuit 120 shown in FIG. 1.

Referring to FIG. 3, the memory device 100 may include the peripheral circuit 120 and the memory cell array 110. The peripheral circuit 120 may be arranged over a substrate, and the memory cell array 110 may be arranged over the peripheral circuit 120. The memory cell array 110 may include the first to j-th memory blocks BLK1 to BLKj. A plurality of bit lines BL may be arranged over the first to j-th memory blocks BLK1 to BLKj.

The plurality of bit lines BL may be arranged spaced apart from each other in the X direction and may extend in the Y direction. The first to j-th memory blocks BLK1 to BLKj may be arranged spaced apart from each other in the Y direction. The first to j-th memory blocks BLK1 to BLKj may be configured to be identical to each other.

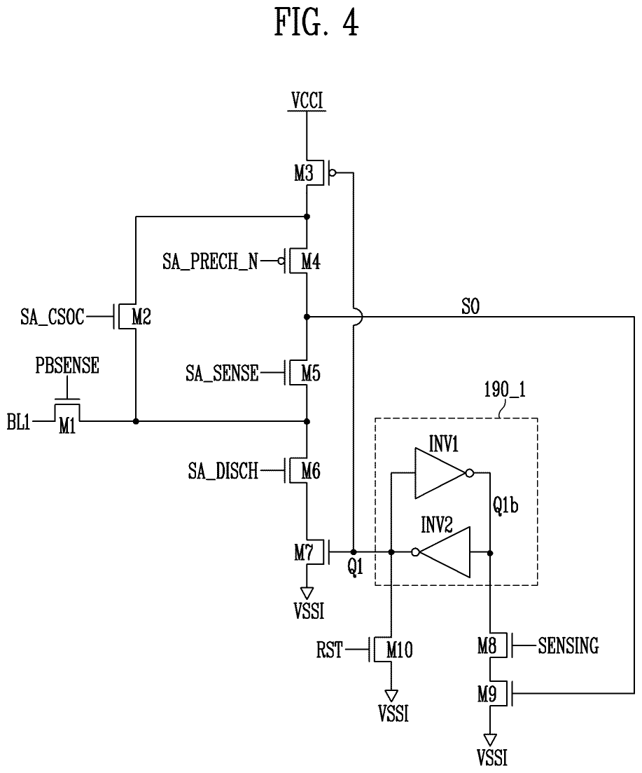

FIG. 4 is a diagram illustrating the first page buffer PB1 among the plurality of page buffers PB1 to PBn of FIG. 1. Although not shown in FIG. 4, the second to n-th page buffers PB2 to PBn may also be implemented in the same structure as in FIG. 4. The circuit shown in FIG. 4 represents a part of the first page buffer PB1, and the configuration may be changed depending on a memory device.

Referring to FIG. 1 and FIG. 4, the first page buffer PB1 is connected to the first memory cell MC1 through the first bit line BL1, and may perform a bit line precharge operation of charging a charge supplied from an internal power voltage VCCI to the first bit line BL1 through first to fifth transistors M1 to M5. The first transistor M1 is controlled by a first sense signal PBSENSE, and the second transistor M2 may be implemented as an N-type transistor controlled by a first precharge signal SA_CSOC. The third transistor M3 may be implemented as a P-type transistor controlled by data stored in a latch 190_1. Further, the fourth transistor M4 may be implemented as an N-type transistor controlled by a second precharge signal SA_PRECH_N, and the fifth transistor M5 may be implemented as an N-type transistor controlled by a second sense signal SA_SENSE.

In addition, the first page buffer PB1 may discharge the charge charged to the first bit line BL1 through the first transistor M1, a sixth transistor M6, and a seventh transistor M7 to an internal ground voltage VSSI. The sixth transistor M6 may be implemented as an N-type transistor controlled by a first discharge signal SA_DISCH, and the seventh transistor M7 may be implemented as an N-type transistor controlled by data stored in the latch 190_1.

In an embodiment, the first page buffer PB1 may include the latch 190_1 including a first inverter INV1 and a second inverter INV2, and may further include a plurality of latches in addition to the latch 190_1. The latch 190_1 may control the bit line precharge operation by turning on or off the third transistor M3 through a main node Q1. An inverting node Q1b and the main node Q1 may store data that is inverted from each other.

A voltage of a sensing node SO during a sensing operation on the first memory cell MC1 is determined based on a threshold voltage of the first memory cell MC1. The latch 190_1 may store a result of sensing the threshold voltage of the first memory cell MC1 through a ninth transistor M9 connected to the sensing node SO. The ninth transistor M9 may be an N-type transistor, and the sensing node SO may be connected to a gate node of the ninth transistor M9.

During a verify operation of the first memory cell MC1, the sensing node SO and the first bit line BL1 may be precharged to a positive voltage level, and a voltage of the first bit line BL1 may be changed or maintained according to the threshold voltage of the first memory cell MC1. When the fifth transistor M5 is turned on, because the voltage of the first bit line BL1 is transferred to the sensing node SO, a voltage of the sensing node SO may be changed or maintained according to the voltage of the first bit line BL1.

When the threshold voltage of the first memory cell MC1 is lower than a verify voltage, the first memory cell MC1 is turned on, so that the voltage of the first bit line BL1 may be lower than a precharge voltage, and a potential of the sensing node SO may transition to a low state lower than a reference voltage. Therefore, the ninth transistor M9 may be turned off. When the threshold voltage of the first memory cell MC1 is higher than the verify voltage, because the first memory cell MC1 is turned off, the voltage of the first bit line BL1 may be maintained at the precharge voltage, and the potential of the sensing node SO may be maintained at a high state higher than the reference voltage. Thus, the ninth transistor M9 may be turned on. The configuration of the first page buffer PB1 may vary depending on a memory device.

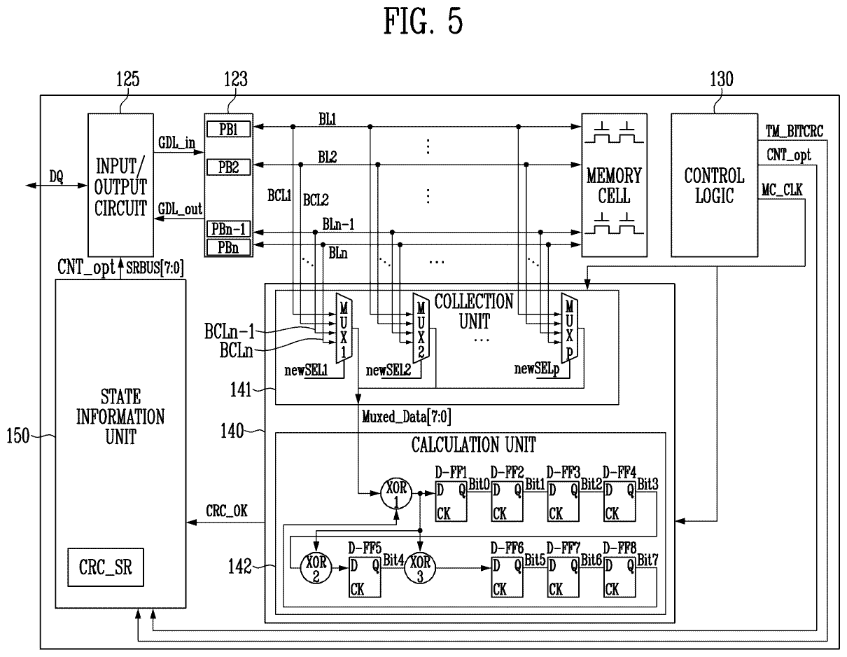

FIG. 5 is a diagram illustrating a cyclic redundancy check unit 140 shown in FIG. 1.

Referring to FIGS. 1 and 5, the memory device 100 for cyclic redundancy check (CRC) includes the control logic 130, the cyclic redundancy check unit 140, and a state information unit 150.

The cyclic redundancy check unit 140 includes a collection unit 141 which collects bit line data, and a calculation unit 142 which performs a cyclic redundancy check on the bit line data.

The collection unit 141 collects bit line data of the first to n-th bit lines BL1 to BLn according to a bit line selection option CNT_opt. In this case, the memory device 100 includes data collection lines BCL1 to BCLn connected to the first to n-th bit lines BL1 to BLn. The data collection lines BCL1 to BCLn serve as a passage for providing the data of the first to n-th bit lines BL1 to BLn to the collection unit 141. Therefore, the collection unit 141 may collect the bit line data through the first to n-th data collection lines BCL1 to BCLn during basic operations such as a read operation or a program operation. The collection unit 141 may collect the bit line data at the end of the program operation or the read operation.

More specifically, the collection unit 141 includes a plurality of multiplexers MUX1 to MUXp. Each of the plurality of multiplexers MUX1 to MUXp is connected to all of the data collection lines BCL1 to BCLn. Accordingly, each of the plurality of multiplexers MUX1 to MUXp is connected to all of the bit lines BL1 to BLn. Here, each of p and n is a natural number greater than 1.

In FIG. 5, the collection unit 141 is illustrated to output 8 data pieces Muxed_Data[7:0] as second bit line data from the multiplexers MUX1 to MUXp and the calculation unit 142 is illustrated to perform cyclic redundancy check with CRC-8, as an example. However, the embodiments of the present disclosure are not limited thereto and the number of data pieces output from the collection unit 141 may vary according to various embodiments.

Each of the plurality of multiplexers MUX1 to MUXp includes an input terminal and an output terminal. Select bit information newSEL1 to newSELp generated based on the bit line selection option CNT_opt provided by the control logic 130 and the first bit line data provided through the data collection lines BCL1 to BCLn are input to the input terminal of each of the plurality of multiplexers MUX1 to MUXp, which select second bit line data from among the first bit line data based on the select bit information newSEL1 to newSELp. The plurality of multiplexers MUX1 to MUXp output the second bit line data to the calculation unit 142.

When a clock MC_CLK from the control logic 130 is input to D flip-flops (not shown), bit information sel1 to selp may be generated according to the number of clocks MC_CLK. The select bit information newSEL1 to newSELp based on the generated bit information sel1 to selp and the bit line selection option CNT_opt. The output signal newSEL1 to newSELp can be generated by performing an operation on the input signal SEL1 to SELp based on the bit line selection option CNT_opt.

Each of the plurality of multiplexers MUX1 to MUXp outputs, from among the first bit line data, 1-bit data piece for the second bit line data based on a corresponding piece of the select bit information newSEL1 to newSELp. The plurality of multiplexers MUX1 to MUXp may output, according to the select bit information newSEL1 to newSELp, multiple-bit data pieces (e.g., data pieces “Muxed_Data[7:0 ]” in FIG. 5), a number or size of which is related to the CRC operation (e.g., CRC-8, CRC-16, CRC-32, and CRC-64) to be performed by the calculation unit 142.

The bit line selection option CNT_opt refers to information on a group of bit lines selected from among the plurality of bit lines BL1 to BLn. The bit line data loaded on the group of bit lines indicated by the bit line selection option CNT_opt is collected by the collection unit 141. The group of bit lines indicated by the bit line selection option CNT_opt may be all bit lines, specific bank bit lines, even bit lines or odd bit lines, which are selected on a specific basis from among the plurality of bit lines BL1 to BLn.

For example, when the bit line selection option CNT_opt is set to all bit lines, all of the first bit line data from the plurality of bit lines BL1 to BLn is selected as the second bit line data. The selected second bit line data is provided to the calculation unit 142.

Alternatively, for example, when the bit line selection option CNT_opt is set to a specific bank, the bit line data corresponding to the specific bank among the first bit line data from the plurality of bit lines BL1 to BLn is selected as the second bit line data. The selected second bit line data is provided to the calculation unit 142.

Alternatively, for example, when the bit line selection option CNT_opt is set to an even-numbered bit line, the bit line data from the plurality of bit lines corresponding to an even number among the first bit line data from the plurality of bit lines BL1 to BLn is selected as the second bit line data. The selected second bit line data is provided to the calculation unit 142.

Alternatively, for example, when the bit line selection option CNT_opt is set to an odd-numbered bit line, the bit line data from the plurality of bit lines corresponding to an odd number among the first bit line data from the plurality of bit lines BL1 to BLn is selected as the second bit line data. The selected second bit line data is provided to the calculation unit 142.

FIG. 5 specifies a method of generating the select bit information newSEL1 to newSELp according to the bit line selection option CNT_opt and selecting the second bit line data based on the select bit information newSEL1 to newSELp from among the first bit line data, but the embodiments are not limited thereto, and a known method may be used.

The collection unit 141 provides the calculation unit 142 with the second bit line data in units of ‘p’ bits, ‘p’ being the number of plurality of multiplexers MUX1 to MUXp. The cyclic redundancy check may be performed by the well-known CRC scheme such as CRC-8, CRC-16, CRC-32, and CRC-64 schemes. For example, when the calculation unit 142 performs the cyclic redundancy check by the CRC-8 scheme, the collection unit 141 may sequentially provide the calculation unit 142 with the second bit line data in units of 8 bits. Accordingly, the calculation unit 142 performs the cyclic redundancy check on the second bit line data in units of 8 bits. In the drawings, for the sake of simplicity, an output line from the collector 141 is illustrated as a single line in FIG. 5, but the collector 141 may include a circuit for dividing bits, and the output line may be represented as a plurality of lines.

The calculation unit 142 performs the cyclic redundancy check (CRC) on the second bit line data in units of ‘p’ bits provided by the collection unit 141. The cyclic redundancy check may be selected from one of CRC-8, CRC-16, CRC-32, and CRC-64. In FIG. 3, the calculation unit 142 performs the cyclic redundancy check by the CRC-8 scheme as an example. However, the embodiments of the present disclosure are not limited thereto, and the calculation unit 142 may use another cyclic redundancy check method.

The calculation unit 142 includes a plurality of D flip-flops D-FF and a plurality of exclusive OR elements.

The reference polynomial used for the cyclic redundancy check in FIG. 5 is as follows. On the other hand, the reference polynomial may be used differently.

$$Polynomial = {x}^{8} + {x}^{5} + {x}^{4} + 1$$

The cyclic redundancy check (CRC) circuit using the above reference polynomial may be implemented by a combination of the plurality of D flip-flops and the plurality of exclusive OR elements, but the embodiments are not limited thereto, and a known cyclic redundancy check (CRC) circuit may also be used. Although the input to a CK terminal of each of the plurality of D flip-flops D-FF1 to D-FF8 is not shown in FIG. 5, the clock MC_CLK of the control logic 130 is input to the CK terminal of each of the plurality of D flip-flops D-FF1 to D-FF8.

The second bit line data of 8 bits and an output value of the eighth D flip-flop D-FF8 are input to a first exclusive OR element XOR1 together. An output value of the first exclusive OR element XOR1 is provided as an input value of the second exclusive OR element XOR2 and the third exclusive OR element XOR3. In addition, the output value of the first exclusive OR element XOR1 is provided as an input value of the first D flip-flop D-FF1.

The first D flip-flop D-FF1 receives the output value of the first exclusive OR element XOR1 and the clock MC_CLK from the control logic 130. An output value of the first D flip-flop D-FF1 is provided as an input value of the second D flip-flop D-FF2.

The second D flip-flop D-FF2 receives the output value of the first D flip-flop D-FF1 and the clock MC_CLK from the control logic 130. An output value of the second D flip-flop D-FF2 is provided as an input value of the third D flip-flop D-FF3.

The third D flip-flop D-FF3 receives the output value of the second D flip-flop D-FF2 and the clock MC_CLK from the control logic 130. An output value of the third D flip-flop D-FF3 is provided as an input value of the fourth D flip-flop D-FF4.

The fourth D flip-flop D-FF4 receives the output value of the third D flip-flop D-FF3 and the clock MC_CLK from the control logic 130. An output value of the fourth D flip-flop D-FF4 is provided as the input value of the second exclusive OR element XOR2.

The second exclusive OR element XOR2 receives the output value of the fourth D flip-flop D-FF4 and the output value of the first exclusive OR element XOR1. An output value of the second exclusive OR element XOR2 is provided as an input value of the fifth D flip-flop D-FF5.

The fifth D flip-flop D-FF5 receives the output value of the second exclusive OR element XOR2 and the clock MC_CLK from the control logic 130. An output value of the fifth D flip-flop D-FF5 is provided as the input value of the third exclusive OR element XOR3.

The third exclusive OR element XOR3 receives the output value of the fifth D flip-flop D-FF5 and the output value of the first exclusive OR element XOR1. An output of the third exclusive OR element XOR3 is provided as an input value of the sixth D flip-flop D-FF6.

The sixth D flip-flop D-FF6 receives the output value of the third exclusive OR element XOR3 and the clock MC_CLK from the control logic 130. An output value of the sixth D flip-flop D-FF6 is provided as an input value of the seventh D flip-flop D-FF7.

The seventh D flip-flop D-FF7 receives the output value of the sixth D flip-flop D-FF6 and the clock MC_CLK from the control logic 130. An output value of the seventh D flip-flop D-FF7 is provided as an input value of the eighth D flip-flop D-FF8.

The eighth D flip-flop D-FF8 receives the output value of the seventh D flip-flop D-FF7 and the clock MC_CLK from the control logic 130. An output value of the eighth D flip-flop D-FF8 is provided as an input value of the first exclusive OR element XOR1.

When the result value of the cyclic redundancy check is 0, the second bit line data is regarded as normal, and when the result value of the cyclic redundancy check is not 0, the second bit line data is regarded as abnormal. FIG. 5 illustrates the calculation unit 142 inverting and outputting the result value of the cyclic redundancy check as an example. In this example, when the output value of the calculation unit 142 is 1, the second bit line data is regarded as normal, and when the output value is not 1, the second bit line data is regarded as abnormal.

The state information unit 150 may store, in a register CRC_SR, the result value CRC_OK of a cyclic redundancy check of the calculation unit 142, and output the result value CRC_OK to the input/output circuit 125 based on a state read command. In the register CRC_SR, the result value CRC_OK may correspond to the bit line selection option CNT_opt. For example, the result value CRC_OK may be stored as cyclic redundancy check result output values SRBUS[7:0], each piece of which corresponds to a corresponding piece of the bit line selection option CNT_opt.

For example, the pieces of the cyclic redundancy check result output values SRBUS[7:0] may comprise a value of ‘NULL’, a result value of the CRC on odd-numbered bit line data, a result value of the CRC on even-numbered bit line data, a result value of the CRC on bit line data corresponding to the seventh bank and an eight bank, a result value of the CRC on bit line data corresponding to the fifth bank and a sixth bank, a result value of the CRC on bit line data corresponding to the third bank and a fourth bank, a result value of the CRC on bit line data corresponding to the first bank and the second bank, and a result value of the CRC on all bit line data. The format of the cyclic redundancy check result output values is not limited thereto, and various settings are possible.

The state information unit 150 may output the cyclic redundancy check result output values SRBUS[7:0] together with the bit line selection option CNT_opt under the control of the control logic 130.

The control logic 130 controls the cyclic redundancy check operation of the cyclic redundancy check unit 140 and the state information providing operation of the state information unit 150.

More specifically, the control logic 130 provides the bit line selection option CNT_opt, the clock MC_CLK, and option setting information TM_BITCRC to the cyclic redundancy check unit 140.

The bit line selection option CNT_opt refers to information on a group of bit lines selected from among the plurality of bit lines BL1 to BLn. The bit line data loaded on the group of bit lines indicated by the bit line selection option CNT_opt is collected by the collection unit 141. The group of bit lines indicated by the bit line selection option CNT_opt may be all bit lines, specific bank bit lines, even bit lines or odd bit lines, which are selected on a specific basis from among the plurality of bit lines BL1 to BLn. The bit line selection option CNT_opt is used for generating select bit information newSEL1 to newSELp.

The clock MC_CLK is a counter clock for the cyclic redundancy check, and is provided to the plurality of D flip-flops provided in each of the collection unit 141 and the calculation unit 142.

The option setting information TM_BITCRC indicates whether or not the bit line selection option CNT_opt is set. When the option setting information TM_BITCRC is enabled, the bit line selection option CNT_opt is regarded as set for outputting the result of the cyclic redundancy check. When the option setting information TM_BITCRC is not enabled, the bit line selection option CNT_opt is regarded as unset for outputting the cyclic redundancy check result.

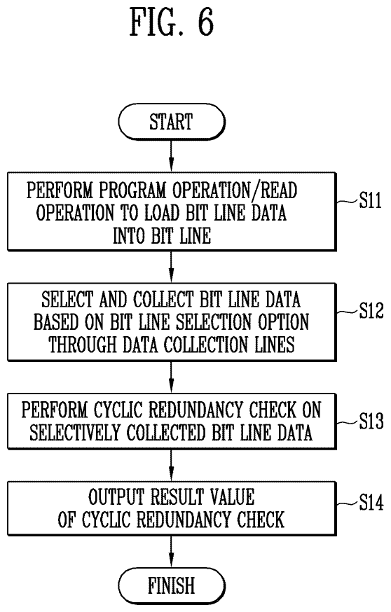

FIG. 6 is a flowchart illustrating a method of operating the memory device 100 according to an embodiment of the present disclosure. Descriptions overlapping with those in FIGS. 1 to 5 are omitted.

Referring to FIG. 6, the method of operating the memory device 100 loads bit line data into a plurality of bit lines by performing a program operation/read operation (S11). To load data into the plurality of bit lines, the control logic 130 of FIG. 1 may control the peripheral circuit 120 of FIG. 1 to perform the program operation or the read operation. The cyclic redundancy check on the bit line data may be performed during the program operation or the read operation such that the bit line data is in the plurality of bit lines. More specifically, the cyclic redundancy check on the bit line data may be performed at the end of the program operation or the read operation. At this time, the data may be input as data that may be subjected to the cyclic redundancy check.

The bit line data is selected and collected based on the bit line selection option CNT_opt through the data collection lines BCL1 to BCLn in FIG. 5 (S12). Here, the bit line selection option CNT_opt may represent one of group option of all bit lines, a specific bank bit line, an even bit line, and an odd bit line. When the clock MC_CLK of the control logic 130 is input to the D flip-flop, the bit information sel1 to selp may be generated according to the number of clocks MC_CLK. The selected bit information newSEL1 to newSELp may be generated based on the generated bit information sel1 to selp and the bit line selection option CNT_opt. The second bit line data is selected from the first bit line data according to the select bit information newSEL1 to newSELp, and the second bit line data is provided in units of ‘p’ bits to the calculation unit 142 in FIG. 5.

To collect data, the select bit information newSEL1 to newSELp according to the bit line selection option CNT_opt may be generated and the first bit line data may be selected as the second bit line data based on the select bit information newSEL1 to newSELp in FIG. 5. However, the method of collecting data is not limited thereto, and the second bit line data may be selected from the first bit line data by using a known method and provided to the calculation unit 142.

Subsequently, the cyclic redundancy check is performed on the selectively collected bit line data (S13). The cyclic redundancy check may be performed by setting the reference polynomial and using the plurality of D flip-flops D-FF0 to D-FF7 in FIG. 5 and the plurality of exclusive OR elements XOR1 to XOR3 configured based on the reference polynomial.

When the result value of the cyclic redundancy check is 0, the second bit line data is regarded as normal, and when the result value of the cyclic redundancy check is not 0, the second bit line data is regarded as abnormal. FIG. 5 illustrates the calculation unit 142 inverting and outputting the result value of the cyclic redundancy check as an example. In this example, when the output value of the calculation unit 142 is 1, the second bit line data is regarded as normal, and when the output value is not 1, the second bit line data is regarded as abnormal.

The state information unit 150 may store, in a register CRC_SR, the result value CRC_OK of cyclic redundancy check of the calculation unit 142, and output the result value CRC_OK to the input/output circuit 125 based on a state read command (S14). The state information unit 150 may output the bit line selection option CNT_opt to the input/output circuit 125 of FIG. 1 together with the cyclic redundancy check result output values SRBUS[7:0], which is the result value CRC_OK, under the control of the control logic 130.

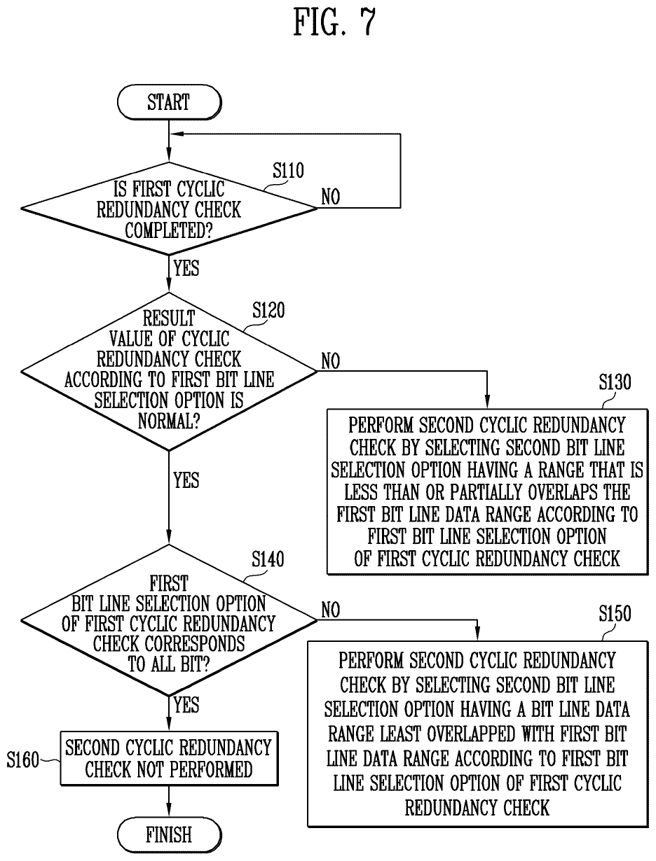

FIG. 7 is a diagram illustrating a controlling method of the cyclic redundancy check operation of the control logic 130 shown in FIGS. 5 and 6.

Referring to FIGS. 5 to 7, the control logic 130 may control the cyclic redundancy check unit 140 and the state information unit 150 based on the bit line selection option CNT_opt. Depending on the result value of a current CRC operation, an additional cyclic redundancy check may be required. The second bit line data may be differently selected from among the first bit line data for respective CRC operations. For the variation of second bit line data for the respective CRC operations, the bit line selection option CNT_opt may be set differently for each of the plural CRC operations.

The control logic 130 may independently change the selection of bit lines for a current CRC operation based on the bit line selection option CNT_opt and the result value of a previous cyclic redundancy check and control the cyclic redundancy check unit 140 to perform the current cyclic redundancy check.

A first CRC operation is performed based on a first bit line selection option and a second CRC operation is performed based on a second bit line selection option. The first CRC operation may be performed before the second CRC operation.

Whether the first cyclic redundancy check has been completed is determined (S110). When the first cyclic redundancy check is completed, it is determined whether the result value of the first cyclic redundancy check according to the first bit line selection option is normal (S120). That is, it is determined whether the result value of the first cyclic redundancy check indicates the second bit line data as normal.

When the result value of the first cyclic redundancy check according to the first bit line selection option is abnormal, i.e., when the result value of the first cyclic redundancy check indicates the second bit line data as abnormal, the second bit line selection option may be set to indicate another group of bit lines. The bit line group indicated by the second bit line option may have a smaller range of bit lines than the bit line group indicated by the first bit line selection option or may have a partially overlapped range with the bit line group indicated by the first bit line selection option. The control logic 130 performs the second cyclic redundancy check based on the second bit line selection option (S130).

For example, when the result value of the first cyclic redundancy check is abnormal and the first bit line selection option indicates odd-numbered bit lines, the second bit line selection option may be set to indicate bit lines of a specific bank. The bit lines of the specific bank may have a smaller range of bit lines than the odd-numbered bit lines or may have a partially overlapped range with the odd-numbered bit lines.

When the result value of the first cyclic redundancy check according to the first bit line selection option is normal, it is determined whether the first bit line selection option indicates all bit lines (S140).

When the result value of the first cyclic redundancy check according to the first bit line selection option is normal and the first bit line selection option indicates a bit line group other than all bit lines, the second bit line selection option may be set to indicate another group of bit lines to perform the second cyclic redundancy check (S150). The bit line group indicated by the second bit line option may have a different range of bit lines than the bit line group indicated by the first bit line selection option or may have a least overlapped range with the bit line group indicated by the first bit line selection option. When the result value of the first cyclic redundancy check according to the first bit line selection option is normal and the first bit line selection option indicates all bit lines, the cyclic redundancy check may be terminated (S160).

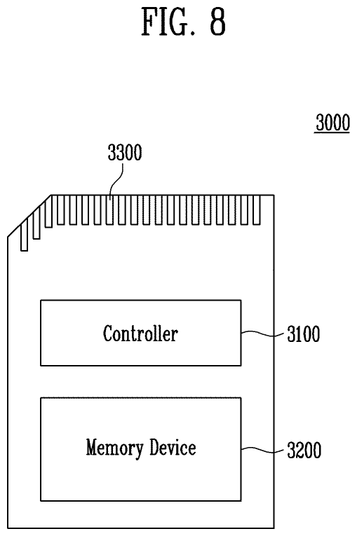

FIG. 8 is a diagram illustrating a memory card system 3000 to which a memory device 3200 according to an embodiment of the present disclosure is applied.

Referring to FIG. 8, the memory card system 3000 includes a controller 3100, the memory device 3200, and a connector 3300.

The controller 3100 is connected to the memory device 3200. The controller 3100 is configured to access the memory device 3200. For example, the controller 3100 may be configured to control a program, read, or erase operation of the memory device 3200, or to control a background operation. The controller 3100 is configured to provide an interface between the memory device 3200 and a host. The controller 3100 is configured to run firmware for controlling the memory device 3200. For example, the controller 3100 may include components such as a Random Access Memory (RAM), a processing unit, a host interface, a memory interface, and an error correction portion.

The controller 3100 may communicate with an external device through the connector 3300. The controller 3100 may communicate with the external device (e.g., a host) according to specific communication protocols. For example, the controller 3100 is configured to communicate with an external device via at least one of a variety of communication standards or interfaces, such as a Universal Serial Bus (USB), a multimedia card (MMC), an embedded MMC (eMMC), a peripheral component interconnect (PCI), a PCI-express (PCI-E), Advanced Technology Attachment (ATA), Serial-ATA, Parallel-ATA, a small computer system interface (SCSI), an enhanced small disk interface (ESDI), Integrated Drive Electronics (IDE), Firewire, Universal Flash Storage (UFS), WiFi, Bluetooth, or NonVolatile Memory express (NVMe). For example, the connector 3300 may be defined by at least one of the various communication standards or interfaces described above.

The memory device 3200 may include memory cells and may be configured the same as the memory device 100 shown in FIG. 1.

The controller 3100 and the memory device 3200 may be integrated into one semiconductor device to form a memory card. For example, the controller 3100 and the memory device 3200 may be integrated into one semiconductor device to form a memory card such as a Personal Computer Memory Card International Association (PCMCIA) memory card, a Compact Flash (CF) card, a smart media card (SM, SMC), a memory stick, a multimedia card (MMC, RS-MMC, MMCmicro, eMMC), Secure Digital (SD) card (SD, miniSD, microSD, SDHC), or a Universal Flash Storage (UFS) device.

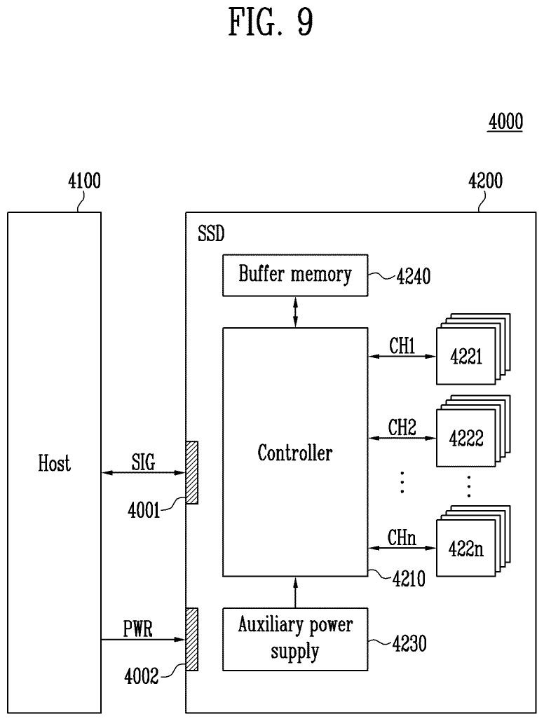

FIG. 9 is a diagram illustrating a Solid-State Drive (SSD) system 4000 to which a memory device according to an embodiment of the present disclosure is applied.

Referring to FIG. 9, the SSD system 4000 includes a host 4100 and an SSD 4200. The SSD 4200 exchanges a signal SIG with the host 4100 through a signal connector 4001, and receives power PWR through a power connector 4002. The SSD 4200 includes a controller 4210, a plurality of memory devices 4221 to 422n, an auxiliary power supply 4230, and buffer memory 4240.

The controller 4210 may control the plurality of memory devices 4221 to 422n in response to the signal received from the host 4100. For example, the signal may be based on an interface of the host 4100 and the SSD 4200. For example, the signal may be defined by at least one of interfaces such as Universal Serial Bus (USB), multimedia card (MMC), embedded MMC (eMMC), peripheral component interconnect (PCI), PCI-express (PCI-E), Advanced Technology Attachment (ATA), Serial-ATA, Parallel-ATA, small computer system interface (SCSI), enhanced small disk interface (ESDI), Integrated Drive Electronics (IDE), Firewire, Universal Flash Storage (UFS), WiFi, Bluetooth, or NVMe interfaces.

The plurality of memory devices 4221 to 422n may include cells capable of storing data. Each of the plurality of memory devices 4221 to 422n may be configured in the same manner as the memory device 100 illustrated in FIG. 1.

The auxiliary power supply 4230 is connected to the host 4100 through the power connector 4002. The auxiliary power supply 4230 may receive a power voltage from the host 4100 and may be charged. The auxiliary power supply 4230 may provide the power voltage of the SSD 4200 when the power supply from the host 4100 is not smooth. For example, the auxiliary power supply 4230 may be located in the SSD 4200 or may be located outside the SSD 4200. For example, the auxiliary power supply 4230 may be located on a main board and may provide auxiliary power to the SSD 4200.

The buffer memory 4240 operates as buffer memory of the SSD 4200. For example, the buffer memory 4240 may temporarily store data received from the host 4100 or data received from the plurality of memory devices 4221 to 422n, or may temporarily store metadata (e.g., a mapping table) of the memory devices 4221 to 422n. The buffer memory 4240 may include volatile memory such as DRAM, SDRAM, DDR SDRAM, or LPDDR SDRAM, or non-volatile memory such as FRAM, ReRAM, STT-MRAM, or PRAM.

According to embodiments of the present disclosure, the reliability of a memory device may be improved by verifying data consistency on a bit line connected between a page buffer and a memory cell.

While detailed embodiments of the present disclosure are disclosed, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope. Furthermore, the embodiments may be combined to form additional embodiments.

What is claimed is:

1. A memory device comprising:
a plurality of memory cells;
a plurality of page buffers storing data in the plurality of memory cells or reading data from the plurality of memory cells;
a plurality of bit lines connected between the plurality of memory cells and the plurality of page buffers; and
a cyclic redundancy check unit including a collection unit collecting bit line data loaded on the plurality of bit lines and a calculation unit performing a cyclic redundancy check (CRC) on the collected bit line data.

2. The memory device of claim 1, wherein the collection unit collects the bit line data loaded on the plurality of bit lines through a plurality of data collection lines connecting the cyclic redundancy check unit and the plurality of bit lines.

3. The memory device of claim 1, wherein the collection unit provides second bit line data selected from among first bit line data loaded on the plurality of bit lines to the calculation unit, the second bit line data selected based on a bit line selection option.

4. The memory device of claim 3, wherein the collection unit includes a plurality of multiplexers receiving the first bit line data and select bit information generated based on the bit line selection option, and outputting the second bit line data selected from the first bit line data based on the select bit information.

5. The memory device of claim 4, wherein each of the plurality of multiplexers is coupled to all of the plurality of bit lines.

6. The memory device of claim 4, wherein the bit line selection option indicates one of an all bit lines group, a specific bank bit line group, an even bit line group, and an odd bit line group.

7. The memory device of claim 4, wherein the collection unit provides the selected second bit line data in units of a specific number of bits to the calculation unit.

8. The memory device of claim 7, further comprising a state information unit outputting a result value of the cyclic redundancy check according to the bit line selection option for a state read command.

9. The memory device of claim 1, wherein the bit line data is loaded on the plurality of bit lines during one of a program operation and a read operation.

10. The memory device of claim 9, wherein the collection unit collects the first bit line data during the program operation or the read operation on the plurality of memory cells.

11. The memory device of claim 3, further comprising a control logic controlling the cyclic redundancy check unit,
wherein the control logic provides the bit line selection option and a clock to the collection unit, and provides the clock to the calculation unit.

12. The memory device of claim 3, further comprising a control logic controlling the cyclic redundancy check unit based on the bit line selection option and a result value of the cyclic redundancy check.

13. The memory device of claim 12, wherein, when a result value of a cyclic redundancy check according to a first bit line selection option is abnormal, the control logic performs a cyclic redundancy check according to a second bit line selection option.

14. The memory device of claim 13, wherein the control logic sets the second bit line selection option such that a group of bit lines indicated by the second bit line selection option partially overlap a group of bit lines indicated by the first bit line selection option.

15. The memory device of claim 12, wherein, when the result value of the cyclic redundancy check according to a first bit line selection option is normal and the first bit line selection option indicates a bit line group other than all bit lines, the control logic performs a cyclic redundancy check according to a second bit line selection option.

16. The memory device of claim 15, wherein the control logic sets the second bit line selection option such that a group of bit lines indicated by the second bit line selection option at least overlap a group of bit lines indicated by the first bit line selection option.

17. A method of operating a memory device, the method comprising:
loading first bit line data into a plurality of bit lines by performing a program operation or a read operation;
selecting and collecting second bit line data from the first bit line data based on a bit line selection option; and
performing a cyclic redundancy check on the second bit line data to generate a result value.

18. The method of claim 17, wherein the bit line selection option indicates one of an all bit lines group, a specific bank bit line group, an even bit line group, and an odd bit line group.

19. The method of claim 17, wherein the second bit line data is collected in units of a specific number of bits required for the cyclic redundancy check.

20. The method of claim 17, wherein collecting the second bit line data is performed before the program operation or the read operation ends.
